(19) United States
(12) Patent Application Publication
(10) Pub. No.: US 2026/0013381 A1
(43) Pub. Date: Jan. 8, 2026

(54) DISPLAY DEVICE

(71) Applicant: Samsung Display Co., LTD., Yongin-si (KR)

(72) Inventors: Young Sang HA, Yongin-si (KR); Rang Kyun MOK, Yongin-si (KR); Tae Ho LEE, Yongin-si (KR)

(21) Appl. No.: 19/039,027

(22) Filed: Jan. 28, 2025

(30) Foreign Application Priority Data
Jul. 2, 2024 (KR) 10-2024-0086872

(51) Int. Cl. H10K 59/80; H10K 59/124

(52) U.S. Cl. CPC H10K 59/8792; H10K 59/124

(57) ABSTRACT

A display device includes a substrate, a light emitting element layer disposed on the substrate and including a plurality of light emission areas, an optical layer disposed on the light emitting element layer and including a plurality of structures and a first light blocking pattern, and a color filter layer disposed on the optical layer and including a plurality of color filters and a second light blocking pattern. The optical layer includes a first planarization layer disposed on the light emitting element layer, including a plurality of holes, and a second planarization layer disposed on the plurality of structures and the first light blocking pattern. The plurality of structures are disposed in the plurality of holes and overlap at least two of the plurality of light emission areas. The first light blocking pattern and the second light blocking pattern do not overlap the plurality of structures.

This application claims priority to Korean Patent Application No. 10-2024-0086872, filed on Jul. 2, 2024, and all the benefits accruing therefrom under 35 U.S.C. § 119, the content of which in its entirety is herein incorporated by reference.

### BACKGROUND

### Field

The present disclosure relates to a display device.

### Description of the Related Art

With the advancement of the information age, the demand for a display device of various forms for displaying an image has increased. For example, display devices have been applied to various electronic devices such as, for example, a smart phone, a digital camera, a laptop computer, a navigator and a smart television.

A display device may be a flat panel display device such as, for example, a liquid crystal display device, a field emission display device and a light emitting display device. A light emitting display device may include an organic light emitting display device that includes an organic light emitting element, an inorganic light emitting display device that includes an inorganic light emitting element such as, for example, an inorganic semiconductor, and a micro light emitting display device that includes a micro light emitting element.

In a display device for a vehicle, in which the display device is disposed in front of a driver and a passenger, the display device may display different respective images to each of the driver and the passenger. In this case, it may be desired to control a viewing angle of an image displayed on the display device for a vehicle such that the image displayed to and viewed by the passenger does not disturb the driver's driving. Techniques are desired for improving luminance such that the images may be clearly viewed by the driver and the passenger.

### SUMMARY

An object of the present disclosure is to provide a display device that may increase luminance and uniform luminance distribution in the range of a viewing angle of a driver and a passenger.

The objects of the present disclosure are not limited to those mentioned above and additional objects of the present disclosure, which are not mentioned herein, will be clearly understood by those skilled in the art from the following description of the present disclosure.

According to an aspect of the present disclosure, a display device includes a substrate, a light emitting element layer disposed on the substrate and including a plurality of light emission areas, an optical layer disposed on the light emitting element layer, wherein the optical layer includes a plurality of structures and a first light blocking pattern, and a color filter layer disposed on the optical layer, wherein the color filter layer includes a plurality of color filters and a second light blocking pattern, wherein the optical layer further includes, a first planarization layer disposed on the light emitting element layer, including a plurality of holes, and a second planarization layer disposed on the plurality of structures and the first light blocking pattern, wherein the plurality of structures are disposed in the plurality of holes and overlap at least two of the plurality of light emission areas, and the first light blocking pattern and the second light blocking pattern do not overlap the plurality of structures.

In an embodiment, the first light blocking pattern includes a plurality of light output portions that respectively overlap the plurality of structures, and the second light blocking pattern includes a plurality of color holes that respectively overlap the plurality of light output portions.

In an embodiment, sizes of the plurality of color holes are respectively larger than sizes of the plurality of light output portions.

In an embodiment, widths of the plurality of light output portions is are respectively equal to widths of upper surfaces of the plurality of structures.

In an embodiment, widths of the plurality of light output portions are respectively greater than widths of upper surfaces of the plurality of structures.

In an embodiment, a refractive index of each of the plurality of structures is greater than a refractive index of the first planarization layer.

In an embodiment, a refractive index of the first planarization layer and a refractive index of the second planarization layer are equal to each other.

In an embodiment, a thickness of the second planarization layer is 1 to 3 times a thickness of the first planarization layer.

In an embodiment, the plurality of structures each include an upper surface, a lower surface, and a side surface, wherein a width of the upper surface is greater than a width of the lower surface, and an angle formed by the upper surface and the side surface ranges from 25° to 45°.

In an embodiment, the display device further includes an encapsulation layer between the light emitting element layer and the optical layer, wherein the first planarization layer and the plurality of structures are directly disposed on the encapsulation layer.

In an embodiment, the plurality of structures overlap at least two light emission areas of the plurality of light emission areas, wherein the at least two light emission areas are configured to emit light of the same color, and the plurality of color filters overlap the at least two light emission areas configured to emit the light of the same color, respectively.

According to an aspect of the present disclosure, a display device includes a substrate, a light emitting element layer disposed on the substrate and including a plurality of light emission areas, an optical layer disposed on the light emitting element layer, wherein the optical layer includes a plurality of structures and a first light blocking pattern, and a color filter layer disposed on the optical layer, wherein the color filter layer includes a plurality of color filters and a second light blocking pattern, wherein the optical layer further includes a first planarization layer disposed on the light emitting element layer, including a plurality of holes, and a second planarization layer disposed on the plurality of structures and the first light blocking pattern, the plurality of structures are disposed in the plurality of holes, and overlap at least two of the plurality of light emission areas, and a thickness of the second planarization layer is 1 to 3 times a thickness of the first planarization layer.

In an embodiment, the first light blocking pattern includes a plurality of light output portions that respectively overlap the plurality of structures, the second light blocking pattern includes a plurality of color holes that respectively overlap the plurality of light output portions, and the plurality of color filters are disposed in the plurality of color holes, respectively.

In an embodiment, sizes of the plurality of color holes are respectively larger than sizes of the plurality of light output portions.

In an embodiment, a refractive index of each of the plurality of structures is larger than a refractive index of the first planarization layer.

In an embodiment, widths of the plurality of light output portions are respectively equal to widths of upper surfaces of the plurality of structures.

In an embodiment, widths of the plurality of light output portions are respectively greater than widths of upper surfaces of the plurality of structures.

In an embodiment, respective lower surfaces of the plurality of structures do not overlap the plurality of light emission areas.

In an embodiment, an upper surface of each of the plurality of structures is mutually aligned and matched with an upper surface of the first planarization layer.

In an embodiment, a thickness of each of the plurality of structures is equal to a thickness of the first planarization layer.

In the display device according to an embodiment, a first light blocking pattern is provided in an optical layer and a thickness ratio of a first planarization layer and a second planarization layer is formed in the range of 1:1 to 1:3, such that high luminance may be uniformly distributed in the range of a viewing angle of 15° to 55°.

In some aspects, the display device according to an embodiment may resolve problems of luminance and crosstalk, which are visually recognizable by a driver and a passenger.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view illustrating a display device according to an embodiment;

FIG. 2 is a plan view illustrating a display device according to an embodiment;

FIG. 3 is a schematic cross-sectional view illustrating a display device, which is taken along line I-I′ of FIG. 2;

FIG. 4 is a schematic view illustrating that a display device according to an embodiment is applied to a vehicle;

FIG. 5 is a schematic cross-sectional view illustrating a display device according to an embodiment;

FIG. 6 is a plan view illustrating light emission areas, color filters and an optical structure of a display device according to an embodiment;

FIG. 7 is a schematic cross-sectional view illustrating a partial area of FIG. 5;

FIG. 8 is a plan view illustrating a first light blocking pattern and light emission areas of a display device according to an embodiment;

FIG. 9 is a plan view illustrating a second light blocking pattern, light output portions and color holes of a display device according to an embodiment;

FIG. 10 is a cross-sectional view illustrating a portion of an optical layer of a display device according to an embodiment;

FIG. 11 is a schematic view illustrating an optical path according to an optical layer that is not provided with a first light blocking pattern of a display device;

FIGS. 12 and 13 are schematic views illustrating an optical path according to examples of an optical layer of a display device according to an embodiment;

FIG. 14 is a graph illustrating luminance according to viewing angles of display devices according to a thickness ratio of a first planarization layer and a second planarization layer;

FIG. 15 is a graph illustrating luminance according to viewing angles when a thickness ratio of a first planarization layer and a second planarization layer of a display device having no first light blocking pattern is 0.95:1;

FIG. 16 is a graph illustrating luminance according to viewing angles of a display device in which a thickness ratio of a first planarization layer and a second planarization layer is 1:1; and

FIG. 17 is a cross-sectional view illustrating a display device according to another embodiment.

### DETAILED DESCRIPTION OF THE DISCLOSURE

Embodiments supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the present invention. Similarly, the second element could also be termed the first element.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Each of the features of the various embodiments of the present disclosure may be combined or combined with each other, in part or in whole, and technically various interlocking and driving are possible. Each embodiment may be implemented independently of each other or may be implemented together in an association.

Hereinafter, the embodiments will be described with reference to the accompanying drawings.

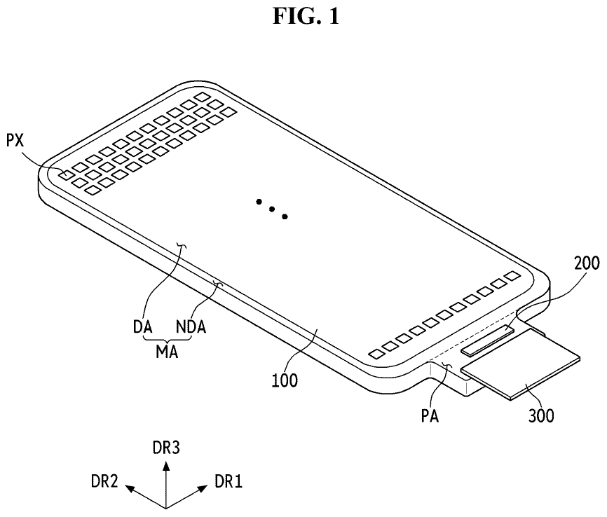

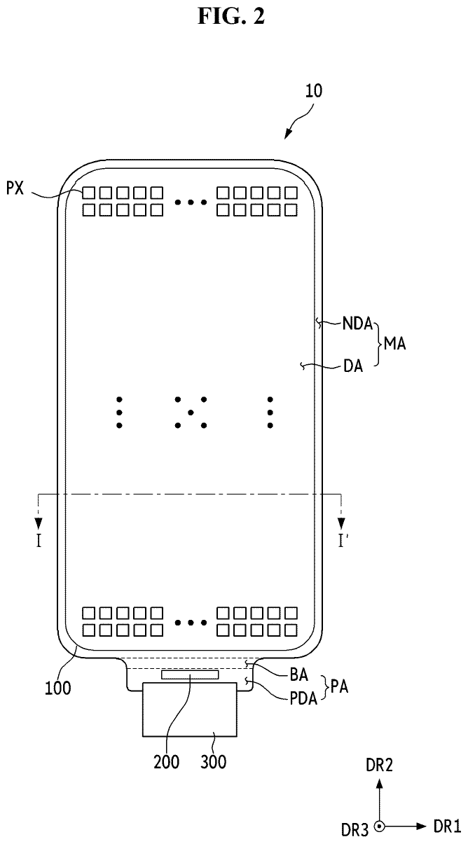

FIG. 1 is an exploded perspective view illustrating a display device according to an embodiment. FIG. 2 is a plan view illustrating a display device according to an embodiment.

Referring to FIGS. 1 and 2, a display device 10 is a device that displays a moving image or a still image, and may be used as a display screen of various products such as, for example, a television, a laptop computer, a monitor, an advertising board and a device for Internet of things (IoT) as well as portable electronic devices such as, for example, a mobile phone, a smart phone, a tablet personal computer (PC), a smart watch, a watch phone, a mobile communication terminal, an electronic diary, an electronic book, a portable multimedia player (PMP), a navigator and an ultra mobile PC (UMPC). The display device 10 may be any one of an organic light emitting display device, a liquid crystal display device, a plasma display device, a field emission display device, an electrophoresis display device, an electrowetting display device, a quantum dot light emitting display device and a micro LED display device. The following description will be based on that the display device 10 is an organic light emitting display device, but embodiments of the present disclosure are not limited thereto.

The display device 10 according to an embodiment may include a display panel 100, a display driving circuit 200, and a circuit board 300.

The display panel 100 may include a plurality of pixels PX arranged in a first direction DR1 and a second direction DR2. Each of the pixels PX may have a planar shape such as, for example, a rectangular shape, a square shape or a rhombus shape. For example, as illustrated in the drawing, each of the pixels PX may have a square planar shape, but is not limited thereto. Each of the pixels PX may have various shapes such as, for example, a polygonal shape, a circular shape and an oval shape on a plane.

In the illustrated drawing, the first direction DR1 and the second direction DR2 are horizontal directions and cross each other. For example, the first direction DR1 and the second direction DR2 may be orthogonal to each other. A third direction DR3 crosses the first direction DR1 and the second direction DR2, and may be, for example, a vertical direction orthogonal to the first direction DR1 and the second direction DR2.

The display panel 100 may include a main area MA and a protrusion area PA protruded from one side of the main area MA.

The main area MA may be formed in a rectangular shaped plane having a short side in the first direction DR1 and a long side in the second direction DR2 crossing the first direction DR1. A corner at which the short side in the first direction DR1 and the long side in the second direction DR2 meet may be rounded to have a predetermined curvature or formed at a right angle. The planar shape of the display device 10 is not limited to the rectangular shape, and may be formed in another polygonal shape, a circular shape or an oval shape. The main area MA may be formed such that the main area MA is flat, but is not limited thereto. The main area MA may include a curved portion formed at left and right ends. In this case, the curved portion may have a constant curvature or a variable curvature.

The main area MA includes a display area DA in which pixels are formed to display an image and a non-display area NDA that is a peripheral area of the display area DA.

Scan lines, data lines and a power line, which are connected to the pixels, as well as the pixels may be disposed in the display area DA. In an example in which the main area MA includes a curved portion, the display area DA may be disposed in the curved portion. In this case, an image of the display panel 100 may be viewed even in the curved portion.

The non-display area NDA may be defined as an area from the outside of the display area DA to an edge of the display panel 100. A scan driver for applying scan signals to the scan lines and link lines for connecting the data lines with the display driving circuit 200 may be disposed in the non-display area NDA.

The protrusion area PA may be protruded from one side of the main area MA. For example, as illustrated in FIG. 2, the protrusion area PA may be protruded from a lower side of the main area MA. A length of the protrusion area PA in the first direction DR1 may be shorter than a length of the main area MA in the first direction DR1.

The protrusion area PA may include a bending area BA and a pad area PDA. In this case, the pad area PDA may be disposed on one side of the bending area BA, and the main area MA may be disposed on the other side of the bending area BA. For example, the pad area PDA may be disposed below the bending area BA, and the main area MA may be disposed above the bending area BA.

The display panel 100 may be flexibly formed such that the display panel 100 is curved, bent, folded or rolled. Therefore, the display panel 100 may be bent in a thickness direction, i.e., the third direction DR3 in the bending area BA. In this case, one surface of the pad area PDA of the display panel 100 is directed upward before the display panel 100 is bent, but one surface of the pad area PDA of the display panel 100 is directed downward after the display panel 100 is bent. As a result, the pad area PDA is disposed below the main area MA and thus may overlap the main area MA.

Pads electrically connected to the display driving circuit 200 and the circuit board 300 may be disposed in the pad area PDA of the display panel 100.

The display driving circuit 200 outputs signals and voltages for driving the display panel 100. For example, the display driving circuit 200 may supply data voltages to the data lines. In some aspects, the display driving circuit 200 may supply a power voltage to the power line and supply scan control signals to the scan driver. The display driving circuit 200 may be formed of an integrated circuit (IC) and then may be mounted on the display panel 100 in the pad area PDA in a chip on glass (COG) mode, a chip on plastic (COP) mode or an ultrasonic bonding mode, but is not limited thereto. For example, the display driving circuit 200 may be mounted on the circuit board 300.

The circuit board 300 may be attached onto the pads by using an anisotropic conductive film. Therefore, lead lines of the circuit board 300 may be electrically connected to the pads. The circuit board 300 may be a flexible printed circuit board, a printed circuit board or a flexible film such as, for example, a chip on film.

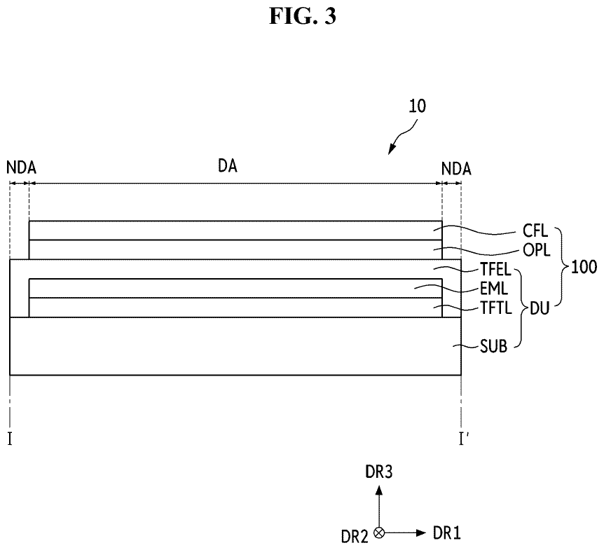

FIG. 3 is a schematic cross-sectional view illustrating a display device, which is taken along line I-I′ of FIG. 2.

Referring to FIG. 3, the display device 10 may include a display panel 100. The display panel 100 may include a display layer DU, an optical layer OPL disposed on the display layer DU, and a color filter layer CFL disposed on the optical layer OPL. The display layer DU may include a substrate SUB, a thin film transistor layer TFTL, a light emitting element layer EML, and a thin film encapsulation layer TFEL.

The substrate SUB may be formed of an insulating material such as, for example, glass, quartz or a polymer resin. An example of the polymer material may include polyethersulphone (PES), polyacrylate (PA), polyarylate (PAR), polyetherimide (PEI), polyethylene napthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or their combination. Alternatively, the substrate may include a metal material.

The substrate SUB may be a rigid substrate, or may be a flexible substrate capable of being subjected to bending, folding, rolling or the like. In an example in which the substrate SUB is a flexible substrate, the substrate may be formed of polyimide (PI), but is not limited thereto.

The thin film transistor layer TFTL may be disposed on the substrate SUB. Scan lines, data lines, power lines, scan control lines, routing lines connecting the pads with the data lines, and the like, as well as thin film transistors of the respective pixels may be formed in the thin film transistor layer TFTL. Each of the thin film transistors may include a gate electrode, a semiconductor layer, a source electrode and a drain electrode.

The thin film transistor layer TFTL may be disposed in the display area DA and the non-display area NDA. In detail, the thin film transistors of the respective pixels, the scan lines, the data lines and the power lines of the thin film transistor layer TFTL may be disposed in the display area DA. The scan control lines and the link lines of the thin film transistor layer TFTL may be disposed in the non-display area NDA.

The light emitting element layer EML may be disposed on the thin film transistor layer TFTL. The light emitting element layer EML may include pixels, which include a first electrode, a light emitting layer and a second electrode, and a pixel defining layer for defining the pixels. The light emitting layer may be an organic light emitting layer that includes an organic material. In this case, the light emitting layer may include a hole transporting layer, an organic light emitting layer and an electron transporting layer. In an example in which a predetermined voltage is applied to the first electrode through the thin film transistor of the thin film transistor layer TFTL and a cathode voltage is applied to the second electrode, holes and electrons are moved to the organic light emitting layer through the hole transporting layer and the electron transporting layer, respectively, and are combined with each other in the organic light emitting layer to emit light. The pixels of the light emitting element layer EML may be disposed in the display area DA.

The thin film encapsulation layer TFEL may be disposed on the light emitting element layer EML. The thin film encapsulation layer TFEL may serve to prevent oxygen or moisture from being permeated into the light emitting element layer EML. To this end, the thin film encapsulation layer TFEL may include at least one inorganic layer. The inorganic layer may be a silicon nitride layer, a silicon oxynitride layer, a silicon oxide layer, a titanium oxide layer or an aluminum oxide layer, but is not limited thereto. In some aspects, the thin film encapsulation layer TFEL may serve to protect the light emitting element layer EML from particles such as, for example, dust. To this end, the thin film encapsulation layer TFEL may include at least one organic layer. The organic layer may be an acryl resin, an epoxy resin, a phenolic resin, a polyamide resin or a polyimide resin, but is not limited thereto.

The thin film encapsulation layer TFEL may be disposed in both the display area DA and the non-display area NDA. In detail, the thin film encapsulation layer TFEL may be disposed such that the thin film encapsulation layer TFEL covers the light emitting element layer EML of the display area DA and the non-display area NDA and covers the thin film transistor layer TFTL of the non-display area NDA.

The optical layer OPL may be disposed on the thin film encapsulation layer TFEL. The optical layer OPL may be disposed to overlap the display area DA. The optical layer OPL may serve to refract light, which is moving at a predetermined angle with respect to the third direction DR3, among the lights emitted from the light emitting element layer EML, toward a left side or a right side.

The display device 10 may further include a cover window. The cover window may be additionally disposed on the optical layer OPL. In this case, the optical layer OPL and the cover window may be attached to each other by a transparent adhesive member such as, for example, an optically clear adhesive (OCA) film.

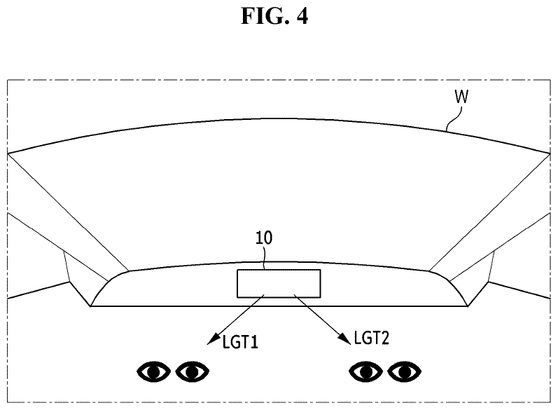

FIG. 4 is a schematic view illustrating that a display device according to an embodiment is applied to a vehicle.

Referring to FIG. 4, the display device 10 according to an embodiment may be, for example, a display device applied to a vehicle. The vehicle may include a vehicle body constituting external appearance of the vehicle and an indoor space defined by the vehicle body. The vehicle body may include a windshield W that protects a driver and a passenger from the outside and provides a field of view to the driver. As illustrated in FIG. 4, the display device 10 may be provided in the indoor space.

In an embodiment, the display device 10 may be disposed on a dashboard provided in the indoor space. For example, the display device 10 may be disposed between the driver's seat and the passenger's seat and provide a map, speed information, and the like to the driver, or may provide entertainment information or the like to the passenger. FIG. 4 illustrates an example of the display device 10 disposed on the dashboard between the driver's seat and the passenger's seat and a driver and a passenger, who view a display screen of the display device 10.

The driver may recognize (or watch) the display screen of the display device 10 through light LGT1 emitted from the display device 10 toward the driver. The passenger may recognize (or watch) the display screen of the display device 10 through light LGT2 emitted from the display device 10 toward the passenger. The display device 10 may differently provide the screen recognized by the driver and the screen recognized by the passenger. However, some light of the light emitted from the display device 10, for example, the light to be emitted toward the passenger may be emitted toward the driver, or the light to be emitted toward the driver may be emitted toward the passenger. In this case, the light may interfere with driving of the driver, and the passenger may view an unnecessary screen (e.g., a screen having information intended for the driver but not the passenger) or two overlapping screens.

In some cases, when the light emitted from the display device 10 is emitted between the driver and the passenger, the light is displayed for each of the driver and the passenger, whereby luminance of the screen may be deteriorated.

Hereinafter, according to an embodiment, the display device 10 capable of controlling a viewing angle to exactly provide a different screen to each of a driver and a passenger and improving luminance of each screen is disclosed.

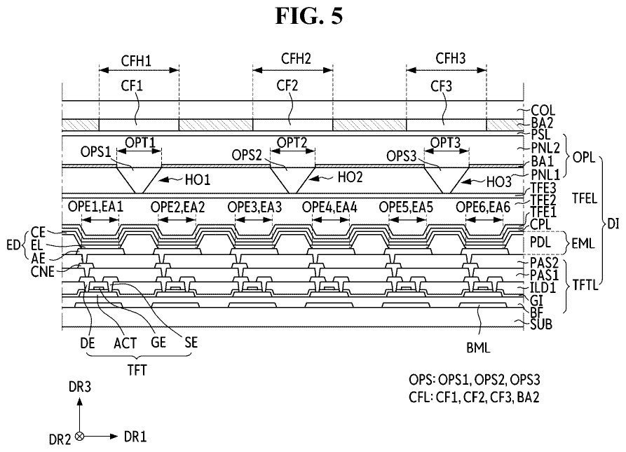

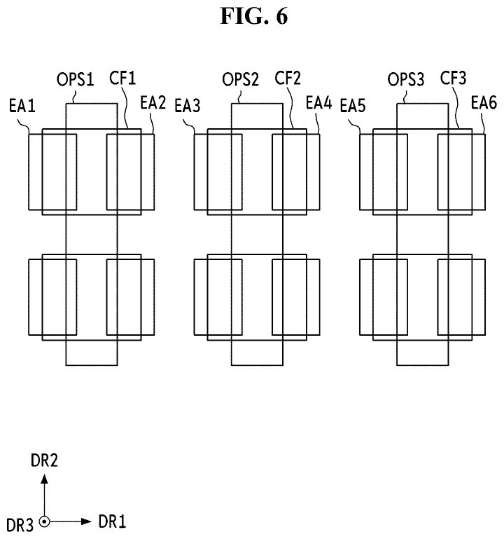

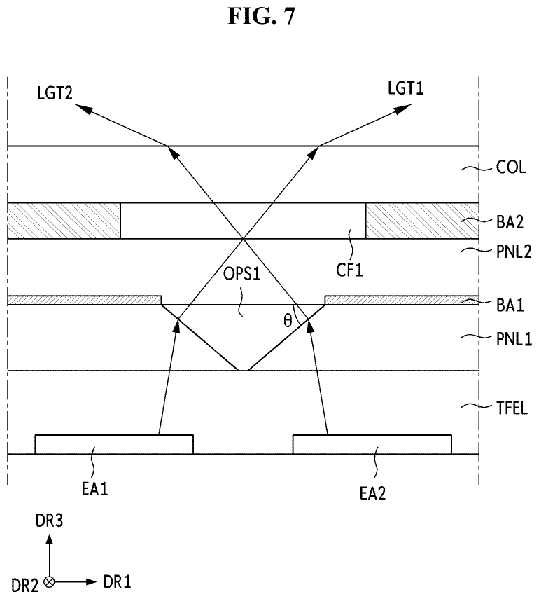

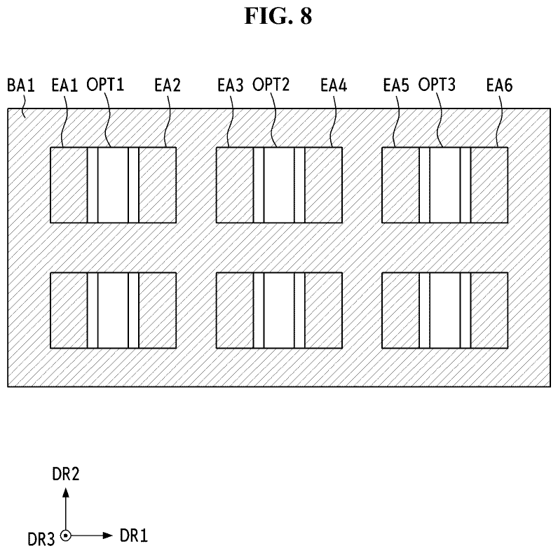

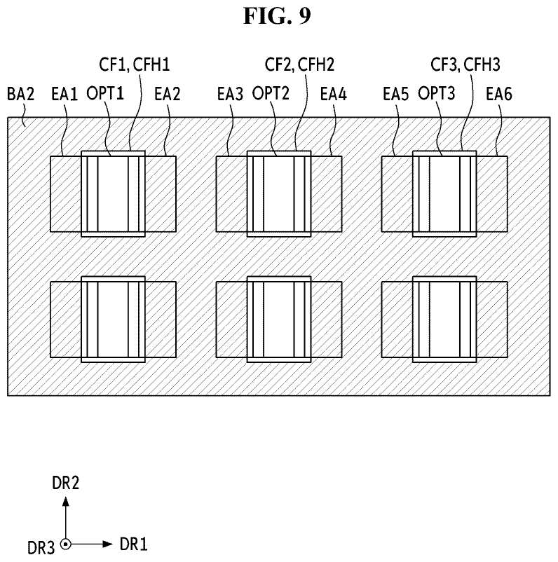

FIG. 5 is a schematic cross-sectional view illustrating a display device according to an embodiment. FIG. 6 is a plan view illustrating light emission areas, color filters and an optical structure of a display device according to an embodiment. FIG. 7 is a schematic cross-sectional view illustrating a partial area of FIG. 5. FIG. 7 illustrates peripheral elements around an optical layer. FIG. 8 is a plan view illustrating a first light blocking pattern and light emission areas of a display device according to an embodiment. FIG. 9 is a plan view illustrating a second light blocking pattern, light output portions and color holes of a display device according to an embodiment.

Referring to FIGS. 5 to 9, the display device 10 according to an embodiment may include a display panel 100. The display panel 100 may include a display layer DU, an optical layer OPL disposed on the display layer DU, and a color filter layer CFL disposed on the optical layer OPL. The display layer DU may include a substrate SUB, a thin film transistor layer TFTL, a light emitting element layer EML, and a thin film encapsulation layer TFEL.

The thin film transistor layer TFTL may be disposed on the substrate SUB. The thin film transistor layer TFTL may include a lower metal layer BML, a buffer layer BF, a thin film transistor TFT, a gate insulating layer GI, an interlayer insulating layer ILD1, a first passivation layer PAS1, a connection electrode CNE, and a second passivation layer PAS2.

The lower metal layer BML may be disposed on the substrate SUB. For example, the lower metal layer BML may be formed as a single layer or multi-layer formed of any one of molybdenum (Mo), aluminum (Al), chromium (Cr), gold (Au), titanium (Ti), nickel (Ni), neodymium (Nd), tantalum (Ta) and copper (Cu), or their alloy.

The buffer layer BF may cover the lower metal layer BML. The buffer layer BF may include an inorganic layer capable of preventing permeation of the air or moisture. For example, the buffer layer BF may include a plurality of inorganic layers that are alternately stacked.

The thin film transistor TFT may be disposed on the buffer layer BF, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the buffer layer BF. The semiconductor layer ACT may overlap the lower metal layer BML and the gate electrode GE in the thickness direction, and may be insulated from the gate electrode GE by the gate insulating layer GI.

The gate electrode GE may be disposed on the gate insulating layer GI. The gate electrode GE may overlap the semiconductor layer ACT, with the gate insulating layer GI interposed between the gate electrode GE and the semiconductor layer ACT.

The gate insulating layer GI may be disposed on the semiconductor layer ACT. For example, the gate insulating layer GI may cover the semiconductor layer ACT and the buffer layer BF, and may insulate the semiconductor layer ACT from the gate electrode GE. The gate insulating layer GI may include contact holes through which the source electrode SE and the drain electrode DE pass.

The interlayer insulating layer ILD1 may cover the gate electrode GE and the gate insulating layer GI. The interlayer insulating layer ILD1 may include contact holes through which the source electrode SE and the drain electrode DE pass. The contact hole of the interlayer insulating layer ILD1 may be connected to the contact hole of the gate insulating layer GI.

The source electrode SE and the drain electrode DE may be disposed on the interlayer insulating layer ILD1. The source electrode SE and the drain electrode DE may be connected to the semiconductor layer ACT through the contact holes of the gate insulating layer GI and the interlayer insulating layer ILD1.

The first passivation layer PAS1 may cover the source and drain electrodes SE and DE and the interlayer insulating layer ILD1. The first passivation layer PAS1 may protect the thin film transistor TFT. The first passivation layer PAS1 may include a contact hole through which the connection electrode CNE passes.

The connection electrode CNE may be disposed on the first passivation layer PAS1. The connection electrode CNE may electrically connect the drain electrode DE of the thin film transistor TFT with the pixel electrode AE of the light emitting element ED. The connection electrode CNE may be inserted into the contact hole formed in the first passivation layer PAS1 to contact the drain electrode DE.

The second passivation layer PAS2 may cover the connection electrode CNE and the first passivation layer PAS1. The second passivation layer PAS2 may include a contact hole through which the pixel electrode AE of the light emitting element ED passes.

The light emitting element layer EML may be disposed on the thin film transistor layer TFTL. The light emitting element layer EML may include a light emitting element ED and a pixel defining layer PDL. The light emitting element ED may include a pixel electrode AE, a light emitting layer EL and a common electrode CO.

The pixel electrode AE may be disposed on the second passivation layer PAS2. The pixel electrode AE may be disposed to overlap any one of openings OPE1, OPE2 and OPE3 of the pixel defining layer PDL. The pixel electrode AE may be electrically connected to the drain electrode DE of the thin film transistor TFT through the connection electrode CNE.

The pixel defining layer PDL may include a plurality of openings OPE1, OPE2, OPE3, OPE4, OPE5 and OPE6, and thus may be disposed on a portion of the pixel electrode AE and the second passivation layer PAS2. The pixel defining layer PDL may include a first opening OPE1, a second opening OPE2, a third opening OPE3, a fourth opening OPE4, a fifth opening OPE5 and a sixth opening OPE6, and each of the openings OPE1, OPE2, OPE3, OPE4, OPE5 and OPE6 may expose a portion of the pixel electrode AE. The openings OPE1, OPE2, OPE3, OPE4, OPE5 and OPE6 may define first to sixth light emission areas EA1, EA2, EA3, EA4, EA5 and EA6, respectively, and may have different areas or sizes. The pixel defining layer PDL may separate and insulate the pixel electrodes AE of the plurality of light emitting elements ED from one another.

Two of the first to sixth light emission areas EA1, EA2, EA3, EA4, EA5 and EA6 may emit light of the same color (i.e., the two light transmission areas may be configured to emit light of the same color). For example, the first light emission area EA1 and the second light emission area EA2 may emit red light of a first color, the third light emission area EA3 and the fourth light emission area EA4 may emit green light of a second color, and the fifth light emission area EA5 and the sixth light emission area EA6 may emit blue light of a third color. Two light emission areas configured to emit the same color may be disposed such that the two light emission areas are adjacent to each other. For example, the first to sixth light emission areas EA1, EA2, EA3, EA4, EA5 and EA6 may be sequentially disposed along the first direction DR1 in the drawing.

The term “adjacent” herein may refer to elements which are relatively close to each other (e.g., within a threshold distance, for example, such that a space is between the elements). For example, for an emission area (e.g., first emission area EA1) described as adjacent to another emission area (e.g., second emission area EA2), another emission area is not present between the adjacent emission areas.

The pixel defining layer PDL may include a light absorbing material which prevents or reduces light reflection. For example, the pixel defining layer PDL may include a polyimide (PI)-based binder and a pigment in which red, green and blue are mixed. Otherwise, the pixel defining layer PDL may include a cardo-based binder resin and a mixture of a lactam black pigment and a blue pigment. Otherwise, the pixel defining layer PDL may include carbon black.

The light emitting layer EL may be disposed on the pixel electrode AE. For example, the light emitting layer EL may be an organic light emitting layer formed of an organic material, but is not limited thereto. In an example in which the light emitting layer EL corresponds to the organic light emitting layer, the thin film transistor TFT applies a predetermined voltage to the pixel electrode AE of the light emitting element ED and the common electrode CO of the light emitting element ED receives a common voltage or a cathode voltage, holes and electrons may move to the light emitting layer EL through a hole transporting layer and an electron transporting layer, respectively, and may be combined with each other in the light emitting layer EL to emit light.

The common electrode CO may be disposed on the light emitting layer EL. For example, the common electrode CO may be implemented in the form of an electrode that is not divided for each of the plurality of pixels and is common to all of the pixels. The common electrode CO may be disposed on the light emitting layer EL in the first to sixth light emission areas EA1, EA2, EA3, EA4, EA5 and EA6, and may be disposed on the pixel defining layer PDL in an area other than the first to sixth light emission areas EA1, EA2, EA3, EA4, EA5 and EA6.

The common electrode CO may receive a common voltage or a low potential voltage. In an example in which the pixel electrode AE receives a voltage corresponding to the data voltage and the common electrode CO receives the low potential voltage, a potential difference is formed between the pixel electrode AE and the common electrode CE, whereby the light emitting layer EL may emit light.

A capping layer CPL may be disposed on the light emitting element layer EML. The capping layer CPL may cover the light emitting element layer EML disposed below the capping layer CPL and prevent oxygen or moisture from being permeated into the light emitting element layer EML. The capping layer CPL may include one or more inorganic layers, and the inorganic layer may include, for example, aluminum oxide, titanium oxide, tantalum oxide, hafnium oxide, zinc oxide, silicon oxide, silicon nitride and/or silicon oxynitride.

The encapsulation layer TFEL may be disposed on the capping layer CPL. The encapsulation layer TFEL may include at least one inorganic layer which prevents oxygen or moisture from being permeated into the light emitting element layer EML. The encapsulation layer TFEL may include at least one organic layer to protect the light emitting element layer EML from particles such as, for example, dust.

The encapsulation layer TFEL may include a first encapsulation layer TFE1, a second encapsulation layer TFE2 and a third encapsulation layer TFE3. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon nitride and/or silicon oxynitride.

The second encapsulation layer TFE2 may include an organic insulating material. The organic insulating material may include an acrylic resin, an epoxy resin, polyimide, and polyethylene. The second encapsulation layer TFE2 may be formed by curing a monomer or coating a polymer.

The optical layer OPL may be disposed on the encapsulation layer TFEL. The optical layer OPL may include a first planarization layer PNL1, a second planarization layer PNL2, an optical structure OPS, a first light blocking pattern BA1, and a passivation layer PSL.

The first planarization layer PNL1 may be disposed on the encapsulation layer TFEL. The first planarization layer PNL1 may be directly disposed on the third encapsulation layer TFE3 of the encapsulation layer TFEL. The first planarization layer PNL1 provides an area in which the optical structure OPS is to be formed, and the first planarization layer PNL1 may planarize a step difference of a lower portion of the encapsulation layer TFEL. The first planarization layer PNL1 may include a first hole HO1, a second hole HO2 and a third hole HO3. The holes HO1, HO2 and HO3 may be disposed spaced apart from one another in the first direction DR1, and may be extended in the second direction DR2. Each of the holes HO1, HO2 and HO3 may partially expose the third encapsulation layer TFE3 of the lower encapsulation layer TFEL.

Each of the holes HO1, HO2 and HO3 may be disposed to correspond to each of the openings OPE1, OPE2, OPE3, OPE4, OPE5 and OPE6 of the light emitting element layer EML and/or each of the light emission areas EA1, EA2, EA3, EA4, EA5 and EA6. For example, the first hole HO1 may partially overlap the first and second openings OPE1 and OPE2, and may partially overlap the first and second light emission areas EA1 and EA2 configured to emit the same color. The second hole HO2 may partially overlap the third and fourth openings OPE3 and OPE4, and may partially overlap the third and fourth light emission areas EA3 and EA4 configured to emit the same color. The third hole HO3 may partially overlap the fifth and sixth openings OPE5 and OPE6 and may partially overlap the fifth and sixth light emission areas EA5 and EA6 configured to emit the same color.

The optical structure OPS may be disposed in the first planarization layer PNL1. For example, the optical structure OPS may be disposed in a filled shape in each of the holes HO1, HO2 and HO3 of the first planarization layer PNL1, and may be in contact with the third encapsulation layer TFE3 exposed by each of the holes HO1, HO2 and HO3. An upper surface of the optical structure OPS may be aligned with and matched with an upper surface of the first planarization layer PNL1. For example, a thickness of the optical structure OPS may be equal to a thickness of the first planarization layer PNL1.

The optical structure OPS may include a first structure OPS1, a second structure OPS2 and a third structure OPS3. The structures OPS1, OPS2 and OPS3 may be disposed spaced apart from one another in the first direction DR1, and may be extended in the second direction DR2. The structures OPS1, OPS2 and OPS3 may be directly in contact with the third encapsulation layer TFE3 of the lower encapsulation layer TFEL.

Each of the structures OPS1, OPS2 and OPS3 may be disposed to correspond to each of the openings OPE1, OPE2, OPE3, OPE4, OPE5 and OPE6 of the light emitting element layer EML and/or each of the light emission areas EA1, EA2, EA3, EA4, EA5 and EA6. For example, the first structure OPS1 may partially overlap the first and second openings OPE1 and OPE2, and may partially overlap the first and second light emission areas EA1 and EA2 configured to emit the same color. The second structure OPS2 may partially overlap the third and fourth openings OPE3 and OPE4, and may partially overlap the third and fourth light emission areas EA3 and EA4 configured to emit the same color. The third structure OPS3 may partially overlap the fifth and sixth openings OPE5 and OPE6, and may partially overlap the fifth and sixth light emission areas EA5 and EA6 configured to emit the same color.

Each of the structures OPS1, OPS2 and OPS3 may have a cross-section generally having the same shape as a prism lens. For example, each of the structures OPS1, OPS2 and OPS3 may be formed in a triangle or a quadrangle in which a width of an upper surface in the cross-section is greater than a width of a lower surface and an angle formed by the upper surface and a side is an acute angle. The lower surface (a surface that is in contact with the third encapsulation film TFE3) of each of the structures OPS1, OPS2 and OPS3 may be disposed so as not to overlap each of the openings OPE1, OPE2, OPE3, OPE4, OPE5 and OPE6 and/or each of the light emission areas EA1, EA2, EA3, EA4, EA5 and EA6.

Sides of each of the structures OPS1, OPS2 and OPS3 may be disposed to overlap each of the openings OPE1, OPE2, OPE3, OPE4, OPE5 and OPE6 and/or each of the light emission areas EA1, EA2, EA3, EA4, EA5 and EA6. For example, one side (e.g., a left side in the drawing) of the first structure OPS1 may partially overlap the first opening OPE1 and the first light emission area EA1, and the other side (e.g., a right side in the drawing) of the first structure OPS1 may partially overlap the second opening OPE2 and the second light emission area EA2. One side (e.g., a left side in the drawing) of the second structure OPS2 may partially overlap the third opening OPE3 and the third light emission area EA3, and the other side (e.g., a right side in the drawing) of the second structure OPS2 may partially overlap the fourth opening OPE4 and the fourth light emission area EA4. One side (e.g., a left side in the drawing) of the third structure OPS3 may partially overlap the fifth opening OPE5 and the fifth light emission area EA5, and the other side (e.g., a right side in the drawing) of the sixth structure OPS6 may partially overlap the sixth opening OPE6 and the sixth light emission area EA6.

A refractive index of the optical structure OPS may be greater than a refractive index of the first planarization layer PNL1. A refractive index of each of the structures OPS1, OPS2 and OPS3 may be greater than the refractive index of the first planarization layer PNL1. Light emitted from each of the light emission areas EA1, EA2, EA3, EA4, EA5 and EA6 may be refracted on an interface between the first planarization layer PNL1 and each of the structures OPS1, OPS2 and OPS3 in accordance with Snell's law. For example, the first light LGT1 emitted from the first light emission area EA1 may move by being refracted to the right from the left side of the first structure OPS1 that is in contact with the first planarization layer PNL1. The second light LGT2 emitted from the second light emission area EA2 may move by being refracted to the left from the right side of the first structure OPS1 that is in contact with the first planarization layer PNL1. That is, since the refractive index of the optical structure OPS is greater than the refractive index of the first planarization layer PNL1, the light emitted from each of the light emission areas EA1, EA2, EA3, EA4, EA5 and EA6 may be visually recognized by the driver and the passenger, respectively.

In some embodiments, the first light blocking pattern BA1 may be disposed on the first planarization layer PNL1. The first light blocking pattern BA1 may partition a plurality of light output portions OPT1, OPT2 and OPT3 disposed to overlap each of the light emission areas EA1, EA2, EA3, EA4, EA5 and EA6. For example, the first light output portion OPT1 may overlap the first and second openings OPE1 and OPE2, and may be disposed to at least partially overlap the first and second light emission areas EA1 and EA2 configured to emit the same color. The second light output portion OPT2 may overlap the third and fourth openings OPE3 and OPE4, and may be disposed to at least partially overlap the third and fourth light emission areas EA3 and EA4 configured to emit the same color. The third light output portion OPT3 may overlap the fifth and sixth openings OPE5 and OPE6, and may be disposed to at least partially overlap the fifth and sixth light emission areas EA5 and EA6 configured to emit the same color.

The first light blocking pattern BA1 may be disposed to have substantially the same size and area as the upper surface of the first planarization layer PNL1. The first light blocking pattern BA1 may block light that does not pass through the optical structure OPS on the first planarization layer PNL1, thereby preventing leakage of light emitted to the front.

A width of each of the light output portions OPT1, OPT2 and OPT3 may be substantially equal to a width of each of the structures OPS1, OPS2 and OPS3 of the optical structure OPS. For example, the width of the first light output portion OPT1 in the first direction DR1 may be equal to the width of the upper surface of the first structure OPS1 in the first direction DR1. The width of each of the light output portions OPT1, OPT2 and OPT3 may affect crosstalk of light emitted from each of the light emission areas EA1, EA2, EA3, EA4, EA5 and EA6. In an example in which the width of the first light output portion OPT1 is greater than the width of the first structure OPS1, light may leak to the front without passing through the first structure OPS1. In an example in which light leakage to the front occurs, the light may be partially recognized by the driver and the passenger, whereby crosstalk may occur. Therefore, in the present embodiment, the first light output portion OPT1 and the first structure OPS1 may be formed such that the width of the first light output portion OPT1 and the width of the first structure OPS1 are substantially equal to each other, which may prevent light leakage to the front and accordingly resolve crosstalk.

The first light blocking pattern BA1 may include a light absorbing material. For example, the first light blocking pattern BA1 may include an inorganic black pigment or an organic black pigment. The inorganic black pigment may be carbon black, and the organic black pigment may include at least one of lactam black, perylene black or aniline black, but is not limited thereto.

The second planarization layer PNL2 may be disposed on the optical structure OPS and the first light blocking pattern BA1. The second planarization layer PNL2 may cover the optical structure OPS and the first light blocking pattern BA1 and planarize a step difference below the second planarization layer PNL2.

The second planarization layer PNL2 may have substantially the same refractive index as the refractive index of the optical structure OPS. Light refracted on the interface between the first planarization layer PNL1 and the optical structure OPS may move to each of color filters CF1, CF2 and CF3 of the color filter layer CFL. In an example in which the refractive index of the second planarization layer PNL2 is different from the refractive index of the optical structure OPS, light is refracted again on the interface between the second planarization layer PNL2 and the optical structure OPS and thus a moving path of light is changed, whereby a luminance or crosstalk problem may occur. Therefore, the refractive index of the second planarization layer PNL2 is formed substantially equal to the refractive index of the optical structure OPS, whereby luminance and crosstalk problems may be resolved. In some aspects, the refractive index of the second planarization layer PNL2 may be greater than the refractive index of the first planarization layer PNL1.

The passivation layer PSL may be disposed on the second planarization layer PNL2. The passivation layer PSL may protect the optical layer OPL disposed below the passivation layer PSL by covering the optical layer OPL. The passivation layer PSL may include at least one inorganic layers, and the inorganic layer may include, for example, aluminum oxide, titanium oxide, tantalum oxide, hafnium oxide, zinc oxide, silicon nitride and/or silicon oxynitride.

The color filter layer CFL may be disposed on the optical layer OPL. The color filter layer CFL may be a reflection control layer that controls reflection of external light. The color filter layer CFL may include a plurality of color filters CF1, CF2 and CF3 and a second light blocking pattern BA2. Each of the color filters may selectively transmit light of a specific wavelength and block or absorb light of another wavelength. The color filter layer CFL may absorb a portion of light incident from the outside of the display device 10 to reduce reflective light due to external light. Therefore, the color filter layer CFL may prevent color distortion due to reflection of external light.

The second light blocking pattern BA2 may be disposed on the passivation layer PSL of the optical layer OPL. The second light blocking pattern BA2 may partition a plurality of color holes CFH1, CFH2 and CFH3 that overlap the light output portions OPT1, OPT2 and OPT3, respectively. For example, the first color hole CFH1 may be disposed to overlap the first light output portion OPT1 and at least a portion of the first opening OPE1, the second opening OPE2, the first light emission area EA1 and the second light emission area EA2. The second color hole CFH2 may be disposed to overlap the second light output portion OPT2 and at least a portion of the third opening OPE3, the fourth opening OPE4, the third light emission area EA3 and the fourth light emission area EA4. The third color hole CFH3 may be disposed to overlap the third light output portion OPT3 and at least a portion of the fifth opening OPE5, the sixth opening OPE6, the fifth light emission area EA5 and the sixth light emission area EA6.

An area or size of each of the color holes CFH1, CFH2 and CFH3 may be larger than an area or size of each of the light output portions OPT1, OPT2 and OPT3. That is, the area of the second light blocking pattern BA2 may be smaller than the area of the first light blocking pattern BA1. As the color holes CFH1, CFH2 and CFH3 of the second light blocking pattern BA2 are formed such that the color holes CFH1, CFH2 and CFH3 are larger than the light output portions OPT1, OPT2 and OPT3 of the first light blocking pattern BA1, the light emitted through the optical layer OPL may be visually recognized by a driver and a passenger, who are located on the side of the display device 10.

The second light blocking pattern BA2 may include a light absorbing material. For example, the second light blocking pattern BA2 may include the same material as the material of the first light blocking pattern BA1. For example, the second light blocking pattern BA2 may include an inorganic black pigment or an organic black pigment, the inorganic black pigment may be carbon black, and the organic black pigment may include at least one of lactam black, perylene black or aniline black.

The plurality of color filters CF1, CF2 and CF3 of the color filter layer CFL may be disposed on the second light blocking pattern BA2 and the passivation layer PSL. The plurality of color filters CF1, CF2 and CF3 may include a first color filter CF1, a second color filter CF2 and a third color filter CF3.

The first color filter CF1 may be disposed in the first color hole CFH1, and may be disposed to overlap the first light output portion OPT1 and the first and second light emission areas EA1 and EA2 configured to emit the same color. The first color filter CF1 may selectively transmit light of the first color (e.g., red) and block or absorb light of the second color (e.g., green) and light of the third color (e.g., blue). For example, the first color filter CF1 may be a red color filter, and may include a red colorant, but is not limited thereto.

The second color filter CF2 may be disposed in the second color hole CFH2, and may be disposed to overlap the second light output portion OPT2 and the third and fourth light emission areas EA3 and EA4 configured to emit the same color. The second color filter CF2 may selectively transmit light of the second color (e.g., green) and may block or absorb light of the third color (e.g., blue) and light of the first color (e.g., red). For example, the second color filter CF2 may be a green color filter, and may include a green colorant, but is not limited thereto.

The third color filter CF3 may be disposed in the third color hole CFH3, and may be disposed to overlap the third light output portion OPT3 and the fifth and sixth light emission areas EA5 and EA6 configured to emit the same color. The third color filter CF3 may selectively transmit light of the third color (e.g., blue) and block or absorb light of the first color (e.g., red) and light of the second color (e.g., green). For example, the third color filter CF3 may be a blue color filter, and may include a green colorant, but is not limited thereto.

The cover layer COL may be disposed on the color filter layer CFL. The cover layer COL may be a glass substrate that faces the substrate SUB, but is not limited thereto. The cover layer COL may be an overcoat layer. The cover layer COL may be a colorless light-transmitting layer that does not have a color of a visible light band. In an example in which the cover layer COL is an overcoat layer, the cover layer COL may include a colorless light-transmitting organic material such as, for example, an acrylic resin or polyimide.

Hereinafter, the optical layer OPL will be described in more detail.

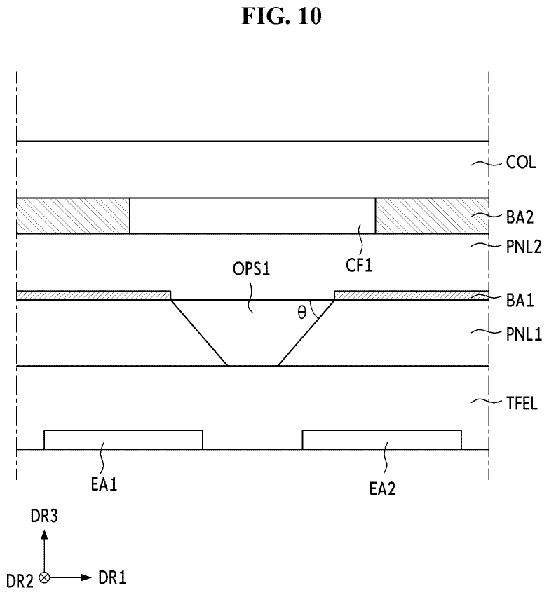

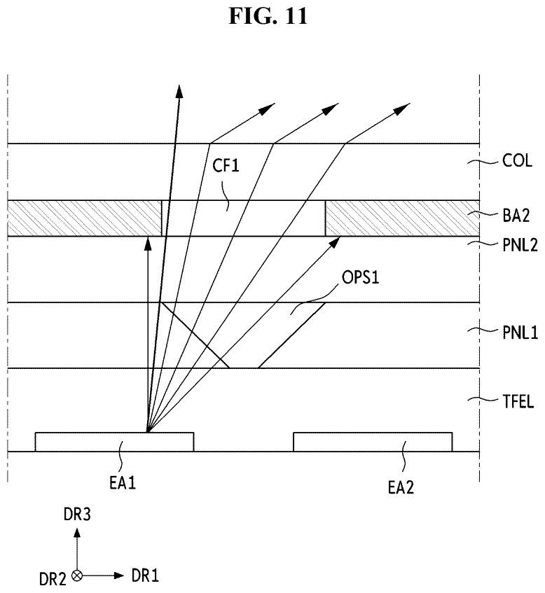

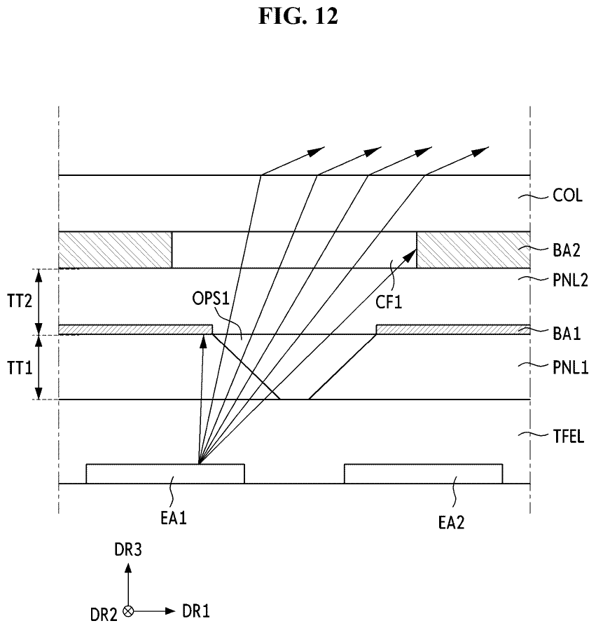

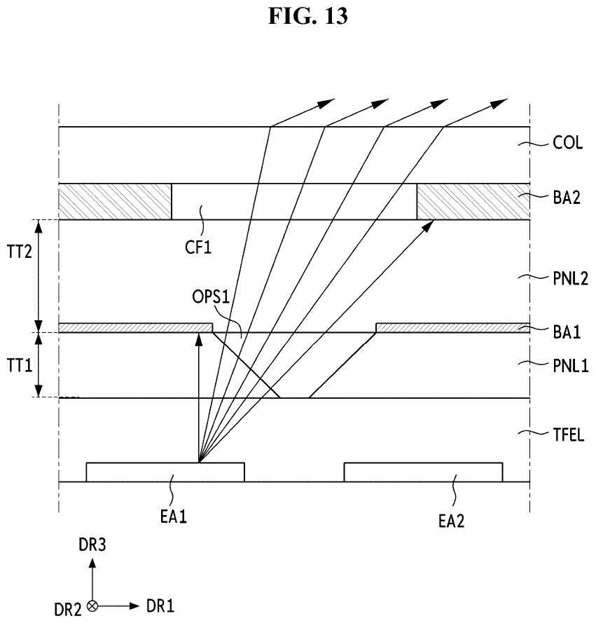

FIG. 10 is a cross-sectional view illustrating a portion of an optical layer of a display device according to an embodiment. FIG. 11 is a schematic view illustrating an optical path according to an optical layer that is not provided with a first light blocking pattern of a display device. FIGS. 12 and 13 are schematic views illustrating an optical path according to examples of an optical layer of a display device according to an embodiment.

FIG. 11 illustrates a case that the first light blocking pattern BA1 is omitted from the optical layer OPL of FIG. 7. FIG. 12 illustrates a case that the first and second planarization layers PNL1 and PNL2 have the same thickness, and FIG. 13 illustrates a case that the thickness of the second planarization layer PNL2 is greater than the thickness of the first planarization layer PNL1. Hereinafter, each of the drawings will be described with reference to FIGS. 5 to 9.

Referring to FIG. 10, the optical structure OPS may have a generally inverted prism shape or a cross-section of an inverted trapezoidal shape. An angle θ formed by the upper surface and the side of the optical structure OPS may be an acute angle. The angle θ formed by the upper surface and the side of each of the structures OPS1, OPS2 and OPS3 may affect crosstalk and luminance. In an embodiment, the angle θ formed by the upper surface and the side of each of the structures OPS1, OPS2 and OPS3 may be in the range of 25° to 45°. In an example in which the angle θ formed by the upper surface and the side of each of the structures OPS1, OPS2 and OPS3 is 25° or more, an angle at which light emitted from each of the light emission areas EA1, EA2, EA3, EA4, EA5 and EA6 is refracted on the interface between the first planarization layer PNL1 and each of the structures OPS1, OPS2 and OPS3 may be adjusted such that a viewing angle recognized by a driver and a passenger may be increased and crosstalk may be avoided. In an example in which the angle θ formed by the upper surface and the side of each of the structures OPS1, OPS2 and OPS3 is 45° or less, the width of the lower surface of each of the structures OPS1, OPS2 and OPS3 is increased such that crosstalk due to the increase in light that moves toward the front through the lower surface of each of the structures OPS1, OPS2 and OPS3 may be reduced or prevented, and the refractive angle of the light may be reduced in association with preventing the viewing angle from being reduced. Therefore, in the present embodiment, the angle θ formed by the upper surface and the side of each of the structures OPS1, OPS2 and OPS3 is in the range of 25° to 45°, such that light may be prevented from moving to the front, thereby resolving crosstalk and improving the viewing angle with respect to the driver and passenger (e.g., improving visibility of the display device 10 (and images displayed by the display device 10) to the driver and passenger).

In some embodiments, as illustrated in FIG. 11, when the optical layer OPL is not provided with the first light blocking pattern BA1, light emitted from the first light emission area EA1, moving to the front may be blocked by the second light blocking pattern BA2. The light emitted from the first light emission area EA1, moving close to the front may transmit the first color filter CF1 without transmitting the first structure OPS1, such that luminance of light visually recognized by the driver and the passenger may be deteriorated and crosstalk may occur.

In an embodiment, the first light blocking pattern BA1 is formed on the optical layer OPL, and the thickness of the second planarization layer PNL2 may be formed in the range of 1 to 3 times relative to the thickness of the first planarization layer PNL1.

As illustrated in FIG. 12, the optical layer OPL according to the embodiment may include the first light blocking pattern BA1, wherein a thickness TT2 of the second planarization layer PNL2 may be equal to a thickness TT1 of the first planarization layer PNL1. In this case, the light emitted from the first light emission area EA1, moving to the front or moving close to the front is absorbed by the first light blocking pattern BA1, whereby crosstalk may be reduced. In some aspects, the amount of light emitted from the first light emission area EA1, moving by being refracted to the right may be increased, such that luminance of light visually recognized by the driver or the passenger may be improved.

In some aspects, as illustrated in FIG. 13, the thickness TT2 of the second planarization layer PNL2 may be 1 to 3 times or less relative to the thickness TT1 of the first planarization layer PNL1. In this case, the amount of light emitted from the first light emission area EA1, moving by being refracted to the right is not significantly different from the light described with reference to FIG. 11 such that luminance of light that is visually recognized by the driver or the passenger may be improved.

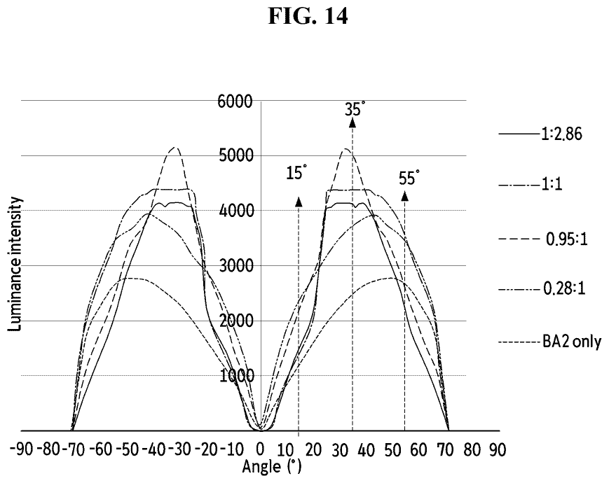

In the present disclosure, the thickness of the second planarization layer PNL2 may be formed in the range of 1 to 3 times the thickness of the first planarization layer PNL1. In other words, a thickness ratio (thickness of the first planarization layer:thickness of the second planarization layer) of the first planarization layer PNL1 and the second planarization layer PNL2 may be formed in the range of 1:1 to 1:3. Hereinafter, luminance characteristics according to the viewing angles of the display device will be described in detail with reference to FIGS. 14 to 16.

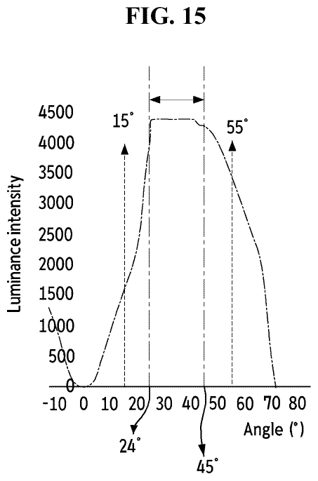

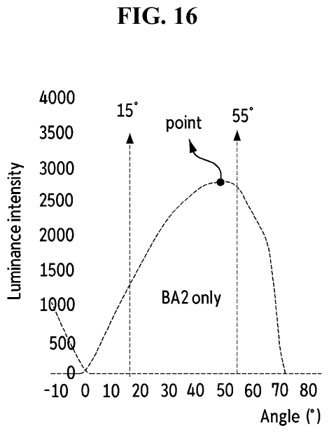

FIG. 14 is a graph illustrating luminance according to viewing angles of display devices according to a thickness ratio of a first planarization layer and a second planarization layer. FIG. 14 illustrates luminance according to viewing angles of display devices in which the thickness ratios (thickness of the firs planarization layer: thickness of the second planarization layers) are 1:2.86, 1:1, 0.95:1 and 0.28:1 and luminance according to the viewing angle when the thickness ratio of the first planarization layer and the second planarization layer is 0.95:1 in the display device (e.g., illustrated in FIG. 11) from which the first light blocking pattern BA1 is omitted. FIG. 15 is a graph illustrating luminance according to the viewing angles when the thickness ratio of the first and second planarization layers is 0.95:1 in the display device from which the first light blocking pattern is omitted. FIG. 16 is a graph illustrating luminance according to the viewing angles of the display device in which the thickness ratio of the first and second planarization layers is 1:1 in FIG. 14.

First, referring to FIGS. 14 to 16, when a thickness ratio of the first light blocking pattern BA1 and the second light blocking pattern BA2 in the display device illustrated in FIG. 12 is 1:1 to 1:2.86, the thickness ratio indicates a luminance peak of about 4000 or more. In some aspects, a ratio occupied by a luminance peak range in a viewing angle range of 15° to 55° indicates 50% or more. In this case, the luminance peak range refers to a period at which the luminance peak is maintained at a certain level within the range of 5%. For example, in FIG. 16, the luminance peak range (indicated by an arrow) may be a viewing angle range of 24° to 45°. That is, in the viewing angle range of 15° to 55°, the viewing angle of 24° to 45° is occupied, such that the luminance peak range occupies about 52.5%. In an example in which the luminance peak range is 50% or more, the example means that a period capable of uniformly illustrating high luminance in the viewing angle range of 15° to 55° is 50% or more.

In some embodiments, in case of a display device in which the first light blocking pattern BA1 is omitted and the second light blocking pattern BA2 is provided (e.g., only BA2 is provided), a luminance peak close to 3000 is indicated, but a luminance peak range, which is a period at which the luminance peak is maintained at a certain level within the range of 5%, is not indicated (and accordingly, not achieved). For example, in FIG. 15, since the luminance peak appears as a point, the luminance peak range is not indicated. Likewise, even when the thickness ratios of the first light blocking pattern BA1 and the second light blocking pattern BA2 are 0.95:1 and 0.28:1, a luminance peak of about 5000 or more or a luminance peak close to 4000 is indicated, but the luminance peak appears as a point, whereby the luminance peak range is not indicated. In an example in which the luminance peak appears as a point, the example means that high luminance is indicated (is achieved) at a specific viewing angle, but uniform luminance distribution is not indicated (is not achieved) in the viewing angle range of 15° to 55°.

The display device according to an embodiment has an advantage in that the first light blocking pattern BA1 is provided in the optical layer OPL and the thickness ratio (thickness of the first planarization layer: thickness of the second planarization layer PNL2) of the first planarization layer PNL1 and the second planarization layer PNL2 is in the range of 1:1 to 1:3, whereby high luminance may be uniformly distributed in the viewing angle range of 15° to 55°.

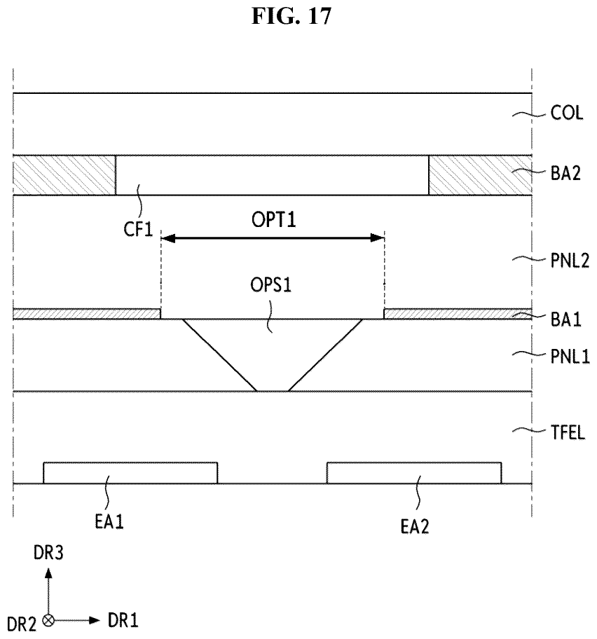

FIG. 17 is a cross-sectional view illustrating a display device according to another embodiment.

Referring to FIG. 17, the present embodiment differs from the other described embodiments in that the width of each of the light output portions OPT1, OPT2 and OPT3 of the first light blocking pattern BA1 is greater than the width of each of the structures OPS1, OPS2 and OPS3 of the optical structure OPS. Hereinafter, the redundant description of the other described embodiments will be omitted, and differences from the other described embodiments will be described. The following description will be based on the first light emission area EA1, the second light output portion EA2, the first light output portion OPT1 and the first color hole CFH1, and may be equally applied to the second light output portion OPT2 and the third light output portion OPT3.

The first light blocking pattern BA1 may be disposed on the first planarization layer PNL1. The first light blocking pattern BA1 may partition the first light output portion OPT1 disposed to overlap each of the light emission areas EA1 and EA2. The first light output portion OPT1 may be disposed to at least partially overlap the first light emission area EA1 and the second light emission area EA2, and may overlap the first color hole CFH1. The first light blocking pattern BA1 may be disposed to have a size and an area, which are smaller than those of the upper surface of the first planarization layer PNL1.

The width of the first light output portion OPT1 may be greater than the width of the first structure OPS1 of the optical structure OPS. For example, the width of the first light output portion OPT1 in the first direction DR1 may be greater than the width of the upper surface of the first structure OPS1 in the first direction DR1. The width of the first light output portion OPT1 may affect crosstalk of light emitted from the first and second light emission areas EA1 and EA2. Therefore, the width of the first light output portion OPT1 may be about 105% or less with respect to 100% of the width of the first structure OPS1. In an example in which the width of the first light output portion OPT1 exceeds 105% with respect to 100% of the width of the first structure OPS1, the amount of light leakage to the front without passing through the first structure OPS1 may be increased. Therefore, in the present embodiment, when the width of the first light output portion OPT1 is greater than 100% to 105% relative to the width of the first structure OPS1, front light leakage may be reduced such that crosstalk may be reduced.

In concluding the detailed description, those skilled in the art will appreciate that many variations and modifications can be made to the example embodiments without substantially departing from the principles of the present invention. Therefore, the disclosed example embodiments of the present disclosure are used in a generic and descriptive sense and not for purposes of limitation.

What is claimed is:

1. A display device comprising:
a substrate;
a light emitting element layer disposed on the substrate and comprising a plurality of light emission areas;
an optical layer disposed on the light emitting element layer, wherein the optical layer comprises a plurality of structures and a first light blocking pattern; and
a color filter layer disposed on the optical layer, wherein the color filter layer comprises a plurality of color filters and a second light blocking pattern,
wherein the optical layer further comprises:
a first planarization layer disposed on the light emitting element layer, comprising a plurality of holes; and
a second planarization layer disposed on the plurality of structures and the first light blocking pattern,
wherein:
the plurality of structures are disposed in the plurality of holes and overlap at least two of the plurality of light emission areas, and
the first light blocking pattern and the second light blocking pattern do not overlap the plurality of structures.

2. The display device of claim 1, wherein:
the first light blocking pattern comprises a plurality of light output portions that respectively overlap the plurality of structures, and
the second light blocking pattern comprises a plurality of color holes that respectively overlap the plurality of light output portions.

3. The display device of claim 2, wherein sizes of the plurality of color holes are respectively larger than sizes of the plurality of light output portions.

4. The display device of claim 2, wherein widths of the plurality of light output portions are respectively equal to widths of upper surfaces of the plurality of structures.

5. The display device of claim 2, wherein widths of the plurality of light output portions are respectively greater than widths of upper surfaces of the plurality of structures.

6. The display device of claim 1, wherein a refractive index of each of the plurality of structures is greater than a refractive index of the first planarization layer.

7. The display device of claim 1, wherein a refractive index of the first planarization layer and a refractive index of the second planarization layer are equal to each other.

8. The display device of claim 1, wherein a thickness of the second planarization layer is 1 to 3 times a thickness of the first planarization layer.

9. The display device of claim 1, wherein:
the plurality of structures each comprise an upper surface, a lower surface, and a side surface, wherein:
a width of the upper surface is greater than a width of the lower surface, and
an angle formed by the upper surface and the side surface ranges from 25° to 45°.

10. The display device of claim 1, wherein:
the plurality of structures overlap at least two light emission areas of the plurality of light emission areas, wherein the at least two light emission areas are configured to emit light of the same color, and
the plurality of color filters overlap the at least two light emission areas configured to emit the light of the same color, respectively.

11. A display device comprising:
a substrate;
a light emitting element layer disposed on the substrate and comprising a plurality of light emission areas;
an optical layer disposed on the light emitting element layer wherein the optical layer comprises a plurality of structures and a first light blocking pattern; and
a color filter layer disposed on the optical layer, wherein the color filter layer comprises a plurality of color filters and a second light blocking pattern,
wherein the optical layer further comprises:
a first planarization layer disposed on the light emitting element layer, comprising a plurality of holes; and
a second planarization layer disposed on the plurality of structures and the first light blocking pattern, wherein:
the plurality of structures are disposed in the plurality of holes and overlap at least two of the plurality of light emission areas, and
a thickness of the second planarization layer is 1 to 3 times a thickness of the first planarization layer.

12. The display device of claim 11, wherein:
the first light blocking pattern comprises a plurality of light output portions that respectively overlap the plurality of structures,
the second light blocking pattern comprises a plurality of color holes that respectively overlap the plurality of light output portions, and
the plurality of color filters are disposed in the plurality of color holes, respectively.

13. The display device of claim 12, wherein sizes of the plurality of color holes are respectively larger than sizes of the plurality of light output portions.

14. The display device of claim 11, wherein a refractive index of each of the plurality of structures is larger than a refractive index of the first planarization layer.

15. The display device of claim 12, wherein widths of the plurality of light output portions are respectively equal to widths of upper surfaces of the plurality of structures.

16. The display device of claim 12, wherein widths of the plurality of light output portions are respectively greater than widths of upper surfaces of the plurality of structures.

17. The display device of claim 11 wherein respective lower surfaces of the plurality of structures do not overlap the plurality of light emission areas.

18. The display device of claim 11, wherein an upper surface of each of the plurality of structures is mutually aligned and matched with an upper surface of the first planarization layer.

19. The display device of claim 11, wherein a thickness of each of the plurality of structures is equal to a thickness of the first planarization layer.

20. An electronic device comprising:
a display device comprising:
a substrate;
a light emitting element layer disposed on the substrate and comprising a plurality of light emission areas;
an optical layer disposed on the light emitting element layer, wherein the optical layer comprises a plurality of structures and a first light blocking pattern; and
a color filter layer disposed on the optical layer, wherein the color filter layer comprises a plurality of color filters and a second light blocking pattern,
wherein the optical layer further comprises:
a first planarization layer disposed on the light emitting element layer, comprising a plurality of holes; and
a second planarization layer disposed on the plurality of structures and the first light blocking pattern,
wherein:
the plurality of structures are disposed in the plurality of holes and overlap at least two of the plurality of light emission areas, and
the first light blocking pattern and the second light blocking pattern do not overlap the plurality of structures.
